(19) United States
(12) Patent Application Publication
(10) Pub. No.: US 2013/0242608 A1
(43) Pub. Date: Sep. 19, 2013

(54) Assembled Mold Frame and Backlight Module Comprising Same

(71) Applicants: ShihHsiang Chen, Shenzhen (CN); Gang Yu, Shenzhen (CN); GeGe Zhou, Shenzhen (CN); WeiFeng Chen, Shenzhen (CN)

(72) Inventors: ShihHsiang Chen, Shenzhen (CN); Gang Yu, Shenzhen (CN); GeGe Zhou, Shenzhen (CN); WeiFeng Chen, Shenzhen (CN)

(73) Assignee: Shenzhen China Star Optoelectronics Technology Co. LTD., Shenzhen City, Guangdong (CN)

(21) Appl. No.: 13/509,999

(22) PCT Filed: Mar. 28, 2012
(86) PCT No.: PCT/CN12/73182

§ 371 Date: May 15, 2012

(30) Foreign Application Priority Data
Mar. 19, 2012 (CN) 201210072924.3

(51) Int. Cl. H05K 7/18; F16M 13/00; G09F 13/04

(52) U.S. Cl. 362/611; 211/182

(57) ABSTRACT

The present invention provides an assembled mold frame and a backlight module including the mold frame. The assembled mold frame includes two opposite first side frames, two opposite second side frames, and four L-shaped connection frames connecting between the first side frames and the second side frames. The first and second side frames are of a linear form. Each first side frame includes a single first side frame unit or a plurality of interconnected first side frame units. Each second side frame includes a single second side frame unit or a plurality of interconnected second side frame units. Each connection frame has two ends that are respectively mating and jointed to one of the first side frame units and one of the second side frame units. The four connection frames, the two first side frames, and the two second side frames are sequentially jointed to form an enclosed rectangular frame.

### BACKGROUND OF THE INVENTION

1. Field of the Invention

The present invention relates to the field of liquid crystal displaying, and in particular to an assembled mold frame and a backlight module comprising the mold frame.

2. The Related Arts

Liquid crystal display (LCD) has a variety of advantages, such as compact device size, low power consumption, and being free of radiation, and is thus widely used. Most of the LCDs that are currently available in the market are backlighting LCDs, which comprise a liquid crystal display panel and a backlight module. The working principle of the liquid crystal display panel is that liquid crystal molecules interposed between two parallel glass plates and a plurality of vertical and horizontal fine electrical wires is arranged between the two glass plates, whereby the liquid crystal molecules are controlled to change direction by application of electricity to refract light emitting from the backlight module for generating images. Since the liquid crystal display panel itself does not emit light, light must be provided by the backlight module in order to generate images. Thus, the backlight module is one of the key components of an LCD and functions to form a planar light source for the liquid crystal display pane.

A conventional backlight module generally comprises a backplane, a backlight source arranged in the backplane, a light guide plate arranged in the backplane, and a mold frame mounted on the backplane. A liquid crystal module, the mold frame is often constructed in the form of a single-piece configuration of a combination of four pieces. With the diversity of specification of the liquid crystal display device, the known way of manufacturing mold frame can no long meet the needs. Consequently, various molds must be provided to suit the needs for modules of different sizes. This, however, cannot lower the expenditure of development and shorten the time period of development.

### SUMMARY OF THE INVENTION

An objective of the present invention is to provide an assembled mold frame, which is formed by assembling first side frames, second side frames, and connection frames, has a low cost, is easy to manufacture, and is size-adjustable by adopting the assembling operation so as to form assembled mold frames of different sizes and realize sharing of manufacturing mold thereby lowering the material cost and the mold cost.

Another objective of the present invention is to provide a backlight module comprising an assembled mold frame, which uses the assembled mold frame discussed above to be easy to manufacture, to have a low cost, and thus lowering the manufacture cost of the entire backlight module.

To achieve the objectives, the present invention provides an assembled mold frame, which comprises two opposite first side frames, two opposite second side frames, and four L-shaped connection frames connecting between the first side frames and the second side frames. The first and second side frames are of a linear form. Each of the first side frames comprises a single first side frame unit or a plurality of interconnected first side frame units. Each of the second side frames comprises a single second side frame unit or a plurality of interconnected second side frame units. Each of the connection frames has two ends that are respectively mating and jointed to one of the first side frame units and one of the second side frame units. The four connection frames, the two first side frames, and the two second side frames are sequentially jointed to form an enclosed rectangular frame. The four connection frames are respectively located at four corners of the rectangular frame. The two first side frames are respectively set at two opposite sides of the rectangular frame and the two second side frames are respectively set at the other two opposite sides of the rectangular frame.

Each of the first side frame units has an end forming a first joint section and an opposite end forming a first joint slot that corresponds to the first joint section. The first side frame units are sequentially jointed through mating engagement between the first joint section and the first joint slot to form the first side frame. Each of the second side frame units has an end forming a second joint section and an opposite end forming a second joint slot that corresponds to the second joint section. The second side frame units are sequentially jointed through mating engagement between the second joint section and the second joint slot to form the second side frame. Two ends of the connection frame respectively form a third joint section and a third joint slot corresponding to the third joint section. The third joint section are mateable and jointed to the first or second joint slot, and the third joint slot are mateable and jointed to the first or second joint section.

The first, second, and third joint slots are of the same structure and the first, second, and third joint sections re of the same structure.

The first, second, and third joint slots are blind slots or through slots and the first, second, and third joint sections have thicknesses respectively corresponding to depths of the first, second, and third joint slots.

The first, second, and third joint slots are opening-diverged slots and the first, second, and third joint sections are respectively receivable in the first, second, and third joint slots.

The first, second, and third joint slots are trapezoidal and the first, second, and third joint sections are trapezoidal corresponding to the first, second, and third joint slots.

The present invention further provides a backlight module, which comprises a backplane, a backlight source arranged inside the backplane, a reflector board arranged inside the backplane, a light guide plate arranged on the reflector board, an optic film positioned on the light guide plate, and an assembled mold frame mounted on the backplane. The assembled mold frame comprises two opposite first side frames, two opposite second side frames, and four L-shaped connection frames connecting between the first side frames and the second side frames. The first and second side frames are of a linear form. Each of the first side frames comprises a single first side frame unit or a plurality of interconnected first side frame units. Each of the second side frames comprises a single second side frame unit or a plurality of interconnected second side frame units. Each of the connection frames has two ends that are respectively mating and jointed to one of the first side frame units and one of the second side frame units. The four connection frames, the two first side frames, and the two second side frames are sequentially jointed to form an enclosed rectangular frame. The four connection frames are respectively located at four corners of the rectangular frame. The two first side frames are respectively set at two opposite sides of the rectangular frame and the two second side frames are respectively set at the other two opposite sides of the rectangular frame.

Each of the first side frame units has an end forming a first joint section and an opposite end forming a first joint slot that corresponds to the first joint section. The first side frame units are sequentially jointed through mating engagement between the first joint section and the first joint slot to form the first side frame. Each of the second side frame units has an end forming a second joint section and an opposite end forming a second joint slot that corresponds to the second joint section. The second side frame units are sequentially jointed through mating engagement between the second joint section and the second joint slot to form the second side frame. Two ends of the connection frame respectively form a third joint section and a third joint slot corresponding to the third joint section. The third joint section are mateable and jointed to the first or second joint slot, the third joint slot are mateable and jointed to the first or second joint section.

The first, second, and third joint slots are of the same structure and the first, second, and third joint sections re of the same structure.

The first, second, and third joint slots are blind slots or through slots and the first, second, and third joint sections have thicknesses respectively corresponding to depths of the first, second, and third joint slots. The first, second, and third joint slots are opening-diverged slots and the first, second, and third joint sections are respectively receivable in the first, second, and third joint slots.

The efficacy of the present invention is that the present invention provides an assembled mold frame, which comprises linear first and second side frames connected by L-shaped connection frames. The cost is low and the manufacture is easy. Further, the assembling process makes it possible to adjust the size in order to provide assembled mold frames of different sizes and realize sharing of common mold in manufacturing assembled mold frames of different sizes thereby lowering the material cost and mold cost. The present invention provides a backlight module that uses an assembled mold frame in order to reduce the manufacture cost while ensuring intensity of light irradiation.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, will be apparent from the following detailed description of embodiments of the present invention, with reference to the attached drawings. In the drawings:

FIG. 1 is an exploded view showing an assembled mold frame according to the present invention;

FIG. 2 is a perspective view of the assembled mold frame according to the present invention; and

FIG. 3 is a cross-sectional view showing a backlight module according to the present invention.

### DETAILED DESCRIPTION OF THE PREFERRED EMBODIMENTS

To further expound the technical solution adopted in the present invention and the advantages thereof, a detailed description is given to preferred embodiments of the present invention and the attached drawings.

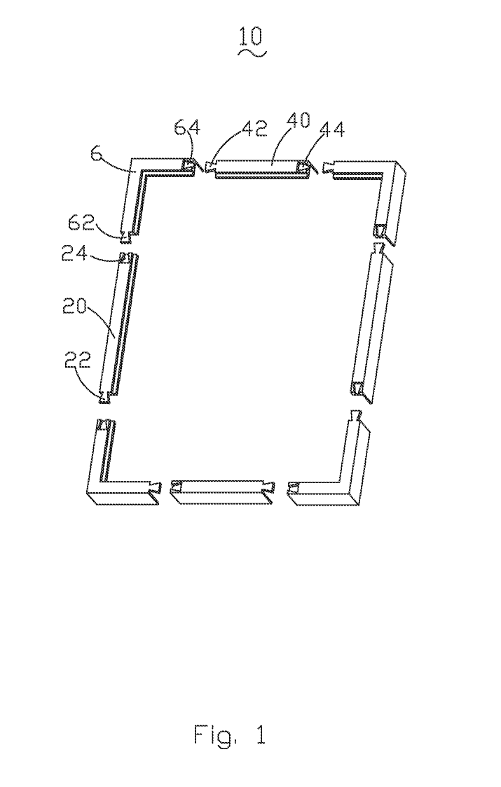

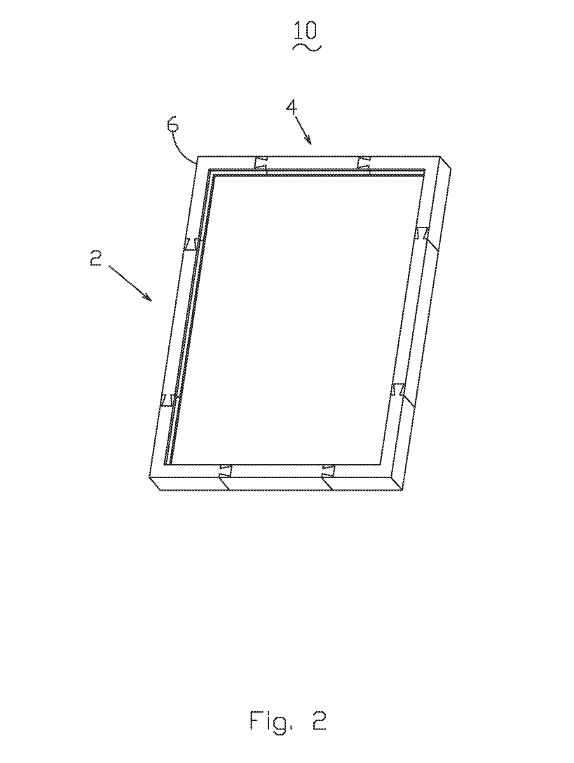

Referring to FIGS. 1 and 2, the present invention provides an assembled mold frame 10, which comprises two opposite first side frames 2, two opposite second side frames 4, and four L-shaped connection frames 6 connecting between the first side frames 2 and the second side frames 4. The first and second side frames 2, 4 are of a linear, straight form. The four connection frames 6, the two first side frames 2, and the two second side frames 4 are sequentially jointed to form an enclosed rectangular frame. The four connection frames 6 are respectively located at four corners of the rectangular frame. The two first side frames 2 are respectively set at two opposite sides of the rectangular frame and the two second side frames 4 are respectively set at the other two opposite sides of the rectangular frame.

Each of the first side frames 2 comprises a single first side frame unit 20 or a plurality of interconnected first side frame units 20. Each of the first side frame units 20 has an end forming a first joint section 22 and an opposite end forming a first joint slot 24 that corresponds to the first joint section 22. The first side frame units 20 are sequentially jointed through mating engagement between the first joint section 22 and the first joint slot 24 to form the first side frame 2, and the first side frame 2 so formed has two opposite ends respectively comprising a first joint section 22 and a first joint slot 24.

Each of the second side frames 4 comprises a single second side frame unit 40 or a plurality of interconnected second side frame units 40. Each of the second side frame units 40 has an end forming a second joint section 42 and an opposite end forming a second joint slot 44 that corresponds to the second joint section 42. The second side frame units 40 are sequentially jointed through mating engagement between the second joint section 42 and the second joint slot 44 to form the second side frame 4, and the second side frame 4 so formed has two opposite ends respectively comprising a second joint section 42 and a second joint slot 44.

Each of the connection frames 6 has two ends that are respectively mating and jointed to a first side frame unit 20 and a second side frame unit 40. The two ends of the connection frame 6 respectively form a third joint section 62 and a third joint slot 64 corresponding to the third joint section 62. The third joint section 62 is mateable and jointed to the first or second joint slot 24, 44 and the third joint slot 64 is mateable and jointed to the first or second joint section 22, 42.

The first, second, and third joint slots 24, 44, 64 are of the same structure and the first, second, and third joint sections 22, 42, 62 are of the same structure for easy assembling.

The assembled mold frame 10 has an overall size that is adjustable through varying the lengths of the first side frames 2 and the second side frames 4 by changing the numbers of the first side frame unit 20 and the second side frame unit 40 in order to suit to liquid crystal display panels of different sizes so as to avoid the increase of cost for re-making of molds. Further, these first side frame units 20 and the second side frame units 40 are respectively made with the same sets of mold, so that the number of re-making of mold is reduced and the manufacture cost is reduced. Further, the connection frames 6 are also made with the same set of mold so that the number of re-making of mold is further reduced and the manufacture cost is further reduced.

The first, second, and third joint slots 24, 44, 64 can be blind slots or through slots. The first, second, and third joint sections 22, 42, 62 are of thicknesses that correspond, respectively, to depths of the first, second, and third joint slots 24, 44, 64.

The first, second, and third joint slots 24, 44, 64 are opening-diverged slots and the first, second, and third joint sections 22, 42, 62 are respectively corresponding to and receivable in the first, second, and third joint slots 24, 44, 64. Since the first, second, and third joint slots 24, 44, 64 are opening-diverged slots, the engagement is secured so that the strength of the assembled mold frame 10 is improved.

Preferably, the first, second, and third joint slots 24, 44, 64 are opening-diverged blind slots and the first, second, and third joint sections 22, 42, 62 have thicknesses that are set to correspond to the depths of the first, second, and third joint slots 24, 44, 64 so that first, second, and third joint sections 22, 42, 62 can be tightly fit into the corresponding first, second, and third joint slots 24, 44, 64 to prevent light leakage caused by fitting gaps and also to ensure surface flatness of the assembled mold frame 10. Further, the first, second, and third joint slots 24, 44, 64 can have a shape of circle, ellipse, triangle, quadrilateral, or polygon. In the instant embodiment, the first, second, and third joint slots 24, 44, 64 are of a trapezoidal shape and the first, second, and third joint sections 22, 42, 62 are also of a trapezoidal shape corresponding to the first, second, and third joint slots 24, 44, 64 so as to ensure secured and enclosed connection of the assembled mold frame 10.

The present invention provides an assembled mold frame, which comprises linear first and second side frames connected by L-shaped connection frames. The cost is low and the manufacture is easy. Further, the assembling process makes it possible to adjust the size in order to provide assembled mold frames of different sizes and realize sharing of common mold in manufacturing assembled mold frames of different sizes thereby lowering the material cost and mold cost.

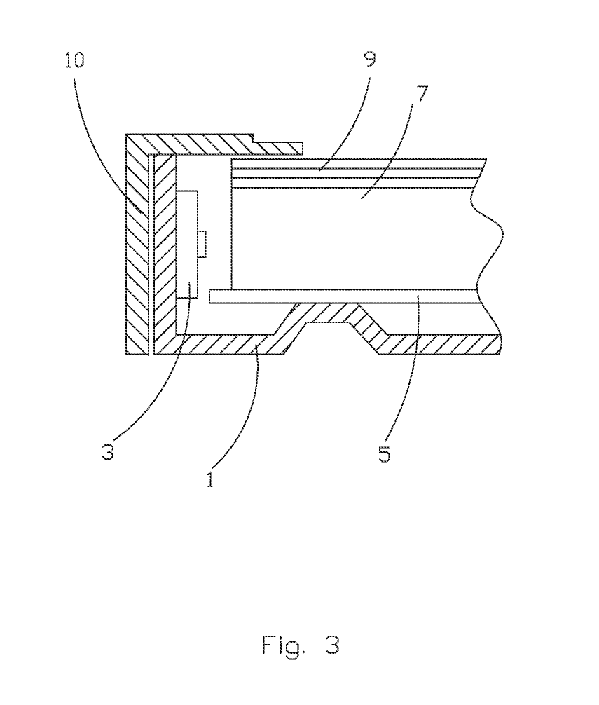

Referring to FIGS. 1 and 3, the present invention also provides a backlight module, which comprises a backplane 1, a backlight source 3 arranged inside the backplane 1, a reflector board 5 arranged inside the backplane 1, a light guide plate 7 arranged on the reflector board 5, optic films 9 positioned on the light guide plate 7, and an assembled mold frame 10 mounted on the backplane 1. The assembled mold frame 10 comprises two opposite first side frames 2, two opposite second side frames 4, and four L-shaped connection frames 6 connecting between the first side frames 2 and the second side frames 4. The first and second side frames 2, 4 are of a linear, straight form. The four connection frames 6, the two first side frames 2, and the two second side frames 4 are sequentially jointed to form an enclosed rectangular frame. The four connection frames 6 are respectively located at four corners of the rectangular frame. The two first side frames 2 are respectively set at two opposite sides of the rectangular frame and the two second side frames 4 are respectively set at the other two opposite sides of the rectangular frame. The structure of the assembled mold frame 10 is described in details previously and repeated description is omitted herein.

The present invention provides a backlight module that uses an assembled mold frame in order to reduce the manufacture cost while ensuring intensity of light irradiation.

Based on the description given above, those having ordinary skills of the art may easily contemplate various changes and modifications of the technical solution and technical ideas of the present invention and all these changes and modifications are considered within the protection scope of right for the present invention.

What is claimed is:

1. An assembled mold frame, comprising two opposite first side frames, two opposite second side frames, and four L-shaped connection frames connecting between the first side frames and the second side frames, the first and second side frames being of a linear form, each of the first side frames comprising a single first side frame unit or a plurality of interconnected first side frame units, each of the second side frames comprising a single second side frame unit or a plurality of interconnected second side frame units, each of the connection frames having two ends that are respectively mating and jointed to one of the first side frame units and one of the second side frame units, the four connection frames, the two first side frames, and the two second side frames being sequentially jointed to form an enclosed rectangular frame, the four connection frames being respectively located at four corners of the rectangular frame, the two first side frames being respectively set at two opposite sides of the rectangular frame and the two second side frames being respectively set at the other two opposite sides of the rectangular frame;
wherein each of the first side frame units has an end forming a first joint section and an opposite end forming a first joint slot that corresponds to the first joint section, the first side frame units being sequentially jointed through mating engagement between the first joint section and the first joint slot to form the first side frame; each of the second side frame units has an end forming a second joint section and an opposite end forming a second joint slot that corresponds to the second joint section, the second side frame units being sequentially jointed through mating engagement between the second joint section and the second joint slot to form the second side frame; and two ends of the connection frame respectively form a third joint section and a third joint slot corresponding to the third joint section, the third joint section being mateable and jointed to the first or second joint slot, the third joint slot being mateable and jointed to the first or second joint section.

2. The assembled mold frame as claimed in claim 1, wherein the first, second, and third joint slots are of the same structure and the first, second, and third joint sections re of the same structure.

3. The assembled mold frame as claimed in claim 1, wherein the first, second, and third joint slots are blind slots or through slots and the first, second, and third joint sections have thicknesses respectively corresponding to depths of the first, second, and third joint slots.

4. The assembled mold frame as claimed in claim 3, wherein the first, second, and third joint slots are opening-diverged slots and the first, second, and third joint sections are respectively receivable in the first, second, and third joint slots.

5. The assembled mold frame as claimed in claim 4, wherein the first, second, and third joint slots are trapezoidal and the first, second, and third joint sections are trapezoidal corresponding to the first, second, and third joint slots.

6. A backlight module, comprising a backplane, a backlight source arranged inside the backplane, a reflector board arranged inside the backplane, a light guide plate arranged on the reflector board, an optic film positioned on the light guide plate, and an assembled mold frame mounted on the backplane, the assembled mold frame comprising two opposite first side frames, two opposite second side frames, and four L-shaped connection frames connecting between the first side frames and the second side frames, the first and second side frames being of a linear form, each of the first side frames comprising a single first side frame unit or a plurality of interconnected first side frame units, each of the second side frames comprising a single second side frame unit or a plurality of interconnected second side frame units, each of the connection frames having two ends that are respectively mating and jointed to one of the first side frame units and one of the second side frame units, the four connection frames, the two first side frames, and the two second side frames being sequentially jointed to form an enclosed rectangular frame, the four connection frames being respectively located at four corners of the rectangular frame, the two first side frames being respectively set at two opposite sides of the rectangular frame and the two second side frames being respectively set at the other two opposite sides of the rectangular frame.

7. The backlight module as claimed in claim 6, wherein each of the first side frame units has an end forming a first joint section and an opposite end forming a first joint slot that corresponds to the first joint section, the first side frame units being sequentially jointed through mating engagement between the first joint section and the first joint slot to form the first side frame; each of the second side frame units has an end forming a second joint section and an opposite end forming a second joint slot that corresponds to the second joint section, the second side frame units being sequentially jointed through mating engagement between the second joint section and the second joint slot to form the second side frame; and two ends of the connection frame respectively form a third joint section and a third joint slot corresponding to the third joint section, the third joint section being mateable and jointed to the first or second joint slot, the third joint slot being mateable and jointed to the first or second joint section.

8. The backlight module as claimed in claim 7, wherein the first, second, and third joint slots are of the same structure and the first, second, and third joint sections re of the same structure.

9. The backlight module as claimed in claim 7, wherein the first, second, and third joint slots are blind slots or through slots and the first, second, and third joint sections have thicknesses respectively corresponding to depths of the first, second, and third joint slots; and the first, second, and third joint slots are opening-diverged slots and the first, second, and third joint sections are respectively receivable in the first, second, and third joint slots.
